(19) United States
(12) Patent Application Publication
(10) Pub. No.: US 2016/0133351 A1
(43) Pub. Date: May 12, 2016

(54) CONDUCTIVE PASTE FOR A SOLAR CELL ELECTRODE

(71) Applicant: E I DU PONT DE NEMOURS AND COMPANY, Wilmington, DE (US)

(72) Inventors: Lapkin K. CHENG, Bear, DE (US); Jeffrey CRAWFORD, West Grove, PA (US); Meijun LU, San Jose, CA (US); Norihiko TAKEDA, Kawasaki (JP)

(21) Appl. No.: 14/931,529

(22) Filed: Nov. 3, 2015

Related U.S. Application Data
(60) Provisional application No. 62/074,671, filed on Nov. 4, 2014.
(60) Provisional application No. 62/074,672, filed on Nov. 4, 2014.

(51) Int. Cl. H01B 1/22; H01L 31/0224

(52) U.S. Cl. CPC H01B 1/22; H01L 31/022425

(57) ABSTRACT

The invention relates to a conductive paste composition useful in the manufacture of photovoltaic cell electrodes, especially electrodes contacting the p-type emitter of an n-type base cell. The paste composition may comprise a source of a conductive metal, a glass frit such as a lead borate, aluminum metal powder, and a boron source that may be at least one of elemental boron, a non-oxide, boron-containing substance, or a combination thereof, all dispersed in an organic vehicle that renders the composition suitable for screen printing or other like application method. Also provided are a semiconductor device such as a photovoltaic cell having an electrode made with the paste composition, and a method for its manufacture.

### CROSS-REFERENCE TO RELATED APPLICATION

This application claims benefit of U.S. Provisional Patent Application Ser. No. 62/074,671, filed Nov. 4, 2014, and entitled “Conductive Paste For A Solar Cell Electrode,” and U.S. Provisional Patent Application Ser. No. 62/074,672, filed Nov. 4, 2014, and entitled “Conductive Paste For A Solar Cell Electrode,” which applications are both incorporated herein in their entirety for all purposes by reference thereto.

### FIELD OF THE INVENTION

This invention relates to a photovoltaic cell, and, more specifically, to a paste composition useful in fabricating an electrode of a photovoltaic cell electrode and a method of manufacturing such an electrode and an associated photovoltaic cell.

### TECHNICAL BACKGROUND

A conventional photovoltaic (PV) cell incorporates a semiconductor structure with a junction, such as a p-n junction formed with an n-type semiconductor and a p-type semiconductor. More specifically, Si solar cells are typically made by adding controlled impurities (called dopants) to purified Si. Different dopants result in either p-type or n-type material, in which there are respectively positive or negative majority charge carriers. The cell structure includes a boundary or junction between p-type and n-type Si. When the cell is illuminated by radiation of an appropriate wavelength, such as sunlight, a potential (voltage) difference across the junction creates free charge carriers. These electron-hole pair charge carriers migrate in the electric field generated by the p-n junction and are collected by electrodes on respective surfaces of the semiconductor. The cell is thus adapted to supply electric current to an electrical load connected to the electrodes, thereby providing electrical energy converted from the incoming solar energy that can do useful work. For the typical n-base configuration, a p-type emitter is located on the side of the cell that is to be exposed to a light source (the “front” side, which in the case of a solar cell is the side exposed to sunlight). A positive electrode contacts the emitter on the front side and a negative electrode contacting the n-type base is located on the other side of the cell (the “back” side). The electrodes ideally make a low electrical resistance contact with the solar cell emitter and base to maximize its performance. Solar-powered photovoltaic systems are considered to be environmentally beneficial in that they reduce the need for fossil fuels used in conventional electric power plants.

US 2006/0102228 discloses a solar cell contact made from a composition that comprises a solids portion and an organic portion. The solids portion comprises from about 85 to about 99 wt. % of silver, and includes about 1 to about 15 wt. % of a glass component that comprises from about 15 to about 75 mol % of PbO, from about 5 to about 50 mol % of SiO₂, and preferably with no B₂O₃. The composition is applied to a semiconductor substrate and fired to form the contact.

Other paste compositions that can be used to fabricate electrodes contacting p-type emitters in n-type base PV cells are disclosed by the following patent applications: U.S. application Ser. No. 13/440132, filed Apr. 5, 2012; U.S. application Ser. No. 13/204027, filed Aug. 5, 2011; and U.S. application Ser. No. 14/197334, filed Mar. 5, 2014. Said applications are all included herein in the entirety for all purposes by reference thereto.

### SUMMARY OF THE INVENTION

An aspect of the present invention provides a conductive paste useful in fabricating a solar cell electrode with desirable electrical properties. The paste composition comprises:
(a) a source of silver metal;
(b) 0.5% to 5% of a fusible material comprising two or more intimately mixed oxides selected from the group consisting of lead oxide (PbO), boron oxide (B₂O₃), zinc oxide (ZnO), bismuth oxide (Bi₂O₃), silicon oxide (SiO₂), aluminum oxide (Al₂O₃), and barium oxide (BaO);
(c) 0.1% to 4% of a boron source comprising at least one of elemental boron, a non-oxide, boron-containing compound, or a combination thereof; and
(d) an organic vehicle in which components (a) to (c) are dispersed,
wherein the percentages are based on weight of the paste composition.

In representative implementations, the fusible material may be a lead borate, i.e., an oxide comprising at least intimately mixed lead and boron oxides. The fusible material optionally may comprise additional oxides that intimately mixed, including silicon and aluminum oxides. Alternatively, the fusible material may be an intimate mixture of oxides that is lead-free.

Another aspect provides a process for forming an electrically conductive structure on a substrate. The process comprises:
(a) providing a substrate having a first major surface and a first passivation layer on at least a portion of the first major surface;
(b) applying the foregoing paste composition onto a preselected portion of the first passivation layer on the first major surface; and
(c) firing the substrate and paste composition thereon, wherein the first passivation layer is penetrated and the silver metal is sintered during the firing to form the electrically conductive structure and provide electrical contact between the electrically conductive metal and the substrate.

For example, the substrate may be a semiconductor comprising a p-type emitter within an emitter region on the first major surface, the preselected portion of the first passivation layer being situated within the emitter region, and an n-type base layer.

Still another aspect provides an electrically conductive structure, such as an electrode, formed from such a conductive paste, or an article such as a semiconductor device or a photovoltaic device that includes such an electrically conductive structure as an electrode.

### BRIEF DESCRIPTION OF THE DRAWINGS

The invention will be more fully understood and further advantages will become apparent when reference is made to the following detailed description of the preferred embodiments of the invention and the accompanying drawings, wherein like reference numerals denote similar elements throughout the several views and in which:

FIGS. 1A through 1F are schematic diagrams illustrating successive stages in a method of manufacturing an N-type base solar cell.

### DETAILED DESCRIPTION

Various aspects of the present disclosure relate to the need for high performance semiconductor and other electronic devices having mechanically robust and durable, high conductivity electrodes as well as processes suitable for their manufacture.

In one aspect, the conductive paste composition provided herein is beneficially employed in the fabrication of such electrodes of photovoltaic devices. Ideally, a paste composition promotes the formation of a metallization that: (a) adheres strongly to the underlying semiconductor substrate; and (b) provides a relatively low resistance contact with the substrate. Suitable paste compositions are believed to aid in etching surface insulating layers often employed in semiconductor structures such as photovoltaic cells to allow good contact between the conductive electrode and the underlying semiconductor.

In an aspect, a paste composition is provided that comprises: a functional conductive component, such as a source of electrically conductive metal; an oxide composition, such as a lead borate or other glass frit; a source of boron, which can be either elemental boron, a non-oxide, boron-containing compound, or a combination thereof; and an organic vehicle in which the source of electrically conductive metal and the oxide composition, along with other optional functional constituents, are dispersed.

Certain embodiments involve a photovoltaic cell that includes one or more conductive structures made with the present paste composition. Such cells may provide in some implementations any combination of one or more of high photovoltaic conversion efficiency, high fill factor, and low series resistance.

Exemplary paste compositions are described below, along with photovoltaic cells and other electronic devices and methods for their manufacture. Some embodiments of the paste composition are beneficially used in forming electrodes that contact n-type regions of Si semiconductors. For this application, the paste composition includes a boron source and optionally a small amount of aluminum metal, in addition to a larger amount of highly conductive silver metal.

In some embodiments, the inclusion of the boron source permits a lower level of aluminum to be used. Reducing aluminum may, in turn, reduce oxidation of aluminum that forms alumina inclusions in the conductive lines that lead to increased line resistance. Alumina may also become dissolved in the oxide composition, deleteriously increasing its melting point. Excess aluminum in some instances leads to emitter damage, degrading electrical performance.

### Source of Conducting Metal

The present paste composition includes a source of an electrically conductive metal. Exemplary metals include without limitation silver, gold, copper, nickel, palladium, platinum, aluminum, zinc, and alloys and mixtures thereof. Silver is beneficial in some embodiments for its processability and high conductivity. However, a composition including at least some non-precious metal may be used to reduce cost.

The conductive metal may be incorporated directly in the present paste composition as a metal powder. In another embodiment, a mixture of two or more such metals or an alloy is directly incorporated. Alternatively, the metal is supplied by a metal oxide or salt that decomposes upon exposure to the heat of firing to form the metal. As used herein, the term “silver” is to be understood as referring to elemental silver metal, alloys of silver, and mixtures thereof, and may further include silver derived from silver oxide (Ag₂O or AgO) or silver salts such as AgCl, AgNO₃, AgOOCCH₃ (silver acetate), AgOOCF₃ (silver trifluoroacetate), Ag₃PO₄ (silver orthophosphate), or mixtures thereof. Any other form of conductive metal compatible with the other components of the paste composition also may be used in certain embodiments. Other metals used in the present paste for the functional conductive material may be similarly derived.

In an implementation, conductive metal is provided by a metal or alloy powder that is configured to form a conductor providing a path by which current generated in a PV cell can be extracted and connected to external circuitry. In various aspects the electrical conductivity of the conductive powder is more than 1×10⁷ Siemens per meter (S/m), more than 3×10⁷ S/m, or more than 5×10⁷ S/m, when measured at a temperature of 20° C. Useful conductive metals include, without limitation, aluminum (Al; 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), and zinc (Zn; 1.64×10⁷ S/m). It is known that the precise conductivity attained by a conductor is dependent on extrinsic properties determined, inter alia, by its preparation and microstructure.

The conductive powder can comprise a powder of any of the metals Ag, Au, Cu, Ni, Pd, Pt, Al, or Zn, or any mixture or alloy thereof. In another embodiment, the metal comprises a powder of Al, Ni, Cu, Ag, or Au, or any mixture or alloy thereof. In still another embodiment, the metal comprises a powder of Ag, Al, Cu, Ni, or a mixture or alloy thereof. In yet another embodiment, the conductive powder comprises a mixture of Ag and Al powders. As shown in the examples below, a solar cell electrode comprising Ag and Al in some instances provides a beneficially lower effective resistance than ones without the concomitant presence of powders of both metals.

Some embodiments of the present paste composition include an alloy powder, which may be, without limitation, a powder of Ag—Al, Ag—Cu, Ag—Ni, or Ag—Cu—Ni.

Electrically conductive metal powder used in the present paste composition may be supplied as finely divided particles having any one or more of the following morphologies: a powder form, a flake form, a spherical form, a rod form, a granular form, a nodular form, a crystalline form, a layered or coated form, other irregular forms, or mixtures thereof. A nodular form may include irregular particles with knotted or rounded shapes. The electrically conductive metal or source thereof may also be provided in a colloidal suspension, in which case the colloidal carrier would not be included in any calculation of weight percentages of the solids of which the colloidal material is part.

The particle size of the metal used in the present paste composition is not subject to any particular limitation. As used herein, “particle size” is intended to refer to “median particle size” or d₅₀, by which is meant the 50% volume distribution size. A particle size distribution may also be characterized by d₉₀, meaning that 90% by volume of the particles are smaller than d₉₀. Volume distribution size may be determined by a number of methods understood by one of skill in the art, including but not limited to laser diffraction and dispersion methods employed by a Microtrac particle size analyzer (Montgomeryville, Pa.). Laser light scattering, e.g., using a model LA-910 particle size analyzer available commercially from Horiba Instruments Inc. (Irvine, Calif.), may also be used.

In various embodiments, the median size of the metal particles ranges from 0.1 μm to 10 μm, or 0.4 μm to 5 μm, or 1 μm to 8 μm, or 2 μm to 5 μm, as measured using the Horiba LA-910 analyzer. In some instances, the particle diameter can affect sintering or other process characteristics of the conductive powder. For example, large silver particles ordinarily sinter more slowly than silver particles of smaller particle diameter.

In some embodiments, metal powder may comprise particles having a plurality of morphologies and/or median particle sizes. For example, the solids portion of the paste composition may include about 80 wt. % to about 90 wt. % silver particles and about 1 wt. % to about 9 wt. % silver flakes. In an embodiment, the solids portion of the paste composition may include about 70 wt. % to about 90 wt. % silver particles and about 1 wt. % to about 9 wt. % silver flakes. In another embodiment, the solids portion of the paste composition may include about 70 wt. % to about 90 wt. % silver flakes and about 1 wt. % to about 9 wt. % of colloidal silver. In a still further embodiment, the solids portion of the paste composition may include about 60 wt. % to about 90 wt. % of silver particles or silver flakes and about 0.1 wt. % to about 20 wt. % of colloidal silver.

The electrically conductive metal used herein, particularly when in powder form, may be coated or uncoated; for example, it may be at least partially coated with a surfactant to facilitate processing. Suitable coating surfactants include, for example, stearic acid, palmitic acid, a salt of stearate, a salt of palm itate, and mixtures thereof. Other surfactants that also may be utilized include lauric acid, oleic acid, capric acid, myristic acid, linoleic acid, and mixtures thereof. Still other surfactants that also may be utilized include polyethylene oxide, polyethylene glycol, benzotriazole, poly(ethylene glycol)acetic acid, and other similar organic molecules. Suitable counter ions for use in a coating surfactant include without limitation hydrogen, ammonium, sodium, potassium, and mixtures thereof. When the electrically conductive metal is silver, it may be coated, for example, with a phosphorus-containing compound.

The conductive metal is present in some embodiments in an amount ranging from a metal source lower limit to a metal source upper limit, the metal source lower limit being one of 65%, 70%, 75%, 80%, or 85%, and the metal source upper limit being one of 85%, 90%, 95%, 99%, or 99.5%, based on the weight of the inorganic solids. Alternatively, the conductive metal may be included in the paste composition in an amount ranging from a metal lower limit to a metal upper limit, the metal lower limit being one of 60%, 65%, 70%, 75%, 80%, or 85%, and the metal upper limit being one of 85%, 90%, 95%, or 97%, based on the weight of the paste composition. In some embodiments, the conductive metal powder may be coated with another metal or other material to alter its reactivity.

The conductive powder can be of ordinary high purity (99%) in an embodiment. However, depending on electrical requirements of the electrode pattern, metal or alloy of greater or lesser purity can also be used. The purity of the conductive powder is more than 95% in an embodiment, and more than 90% in another embodiment.

The conductive powder can contain two or more different metals or alloys, which can have the same or different composition, particle size, or morphology. The conductive powder can comprise Al powder in an embodiment. In some embodiments, inclusion of both Ag and Al powders is found to improve any one or more of the electrical properties of a solar cell, e.g. as shown hereinbelow.

In an embodiment, the paste composition includes powders of both a high conductivity metal (e.g., any one or more of Ag, Au, Cu, and mixtures thereof) and Al, with the high conductivity metal content ranging from a high conductivity metal lower limit to a high conductivity metal upper limit and the Al content ranging from an Al lower limit to an Al upper limit. The high conductivity metal lower limit may be any of 65%, 70%, 75%, 80%, or 85% and the high conductivity metal upper limit may be any of 85%, 90%, 95%, or 97%, while the Al lower limit may be any of 0%, 0.1%, 0.2%, 0.25%, or 0.5%, and the Al upper limit may be any of 1%, 2%, 3%, 4%, or 5%, all by weight of the paste composition.

In some embodiments, the electrically conductive metal is substantially Al-free, meaning that the paste composition does not include aluminum (Al) metal or any aluminum-containing material that decomposes to provide aluminum metal or aluminum-containing metal or metal alloy, and that the amount of aluminum present as an impurity ordinarily is less than 0.1 wt. %.

Particle diameter (d₅₀) of the Al powder or Al containing alloy powder can be not smaller than 1 μm in an embodiment, not smaller than 2.0 μm in another embodiment, and not smaller than 3.0 μm in another embodiment. The particle diameter (d₅₀) of the Al powder or Al containing alloy powder is not larger than 20 μm in an embodiment, not larger than 12 μm in another embodiment, and not larger than 8 μm in another embodiment. With such particle diameter of the aluminum powder, the electrode can have better contact with a semiconductor layer.

The purity of the Al powder or Al containing alloy powder can be 99% or higher. The purity of the Al powder or Al containing alloy powder can be more than 95% in an embodiment, and more than 90% in another embodiment.

### Oxide Component

The oxide component used in the paste composition described herein is believed to promote sintering of the conductive powder and the formation of an electrode or like conductive structure that is mechanically robust and tenaciously adherent to the substrate. In particular, the oxide composition is believed to combine with, dissolve, etch, or otherwise penetrate some or all of the thickness of the passivation or anti-reflective layer typically present on at least the front surface of a photovoltaic cell during a firing operation.

In some embodiments, the present oxide composition is a glass. Glass in the form of finely divided particles is commonly termed “frit.” As used herein, the term “glass” refers to a particulate solid form, such as an oxide or oxyfluoride, that is at least predominantly amorphous, meaning that short-range atomic order is preserved in the immediate vicinity of any selected atom, that is, in the first coordination shell, but dissipates at greater atomic-level distances (i.e., there is no long-range periodic order). Hence, the X-ray diffraction pattern of a fully amorphous material exhibits broad, diffuse peaks, and not the well-defined, narrow peaks of a crystalline material. In the latter, the regular spacing of characteristic crystallographic planes give rise to the narrow peaks, whose position in reciprocal space is in accordance with Bragg's law. A glass material also does not show a substantial crystallization exotherm upon heating close to or above its glass transition temperature or softening point, Tg, which is defined as the second transition point seen in a differential thermal analysis (DTA) scan. In an embodiment, the softening point of glass material used in the present paste composition is in the range of 300 to 800° C. In other embodiments, the softening point is in the range of 250 to 650° C., or 300 to 500° C., or 300 to 400° C.

It is contemplated that some or all of the oxide material herein may be composed of material that exhibits some degree of crystallinity. For example, in some embodiments, a plurality of oxides are melted together, resulting in a material that is partially amorphous and partially crystalline. As would be recognized by a skilled person, such a material would produce an X-ray diffraction pattern having narrow, crystalline peaks superimposed on a pattern with broad, diffuse peaks. Alternatively, one or more constituents, or even substantially all of the fusible material, may be predominantly or even substantially fully crystalline. In an embodiment, crystalline material useful in the fusible material of the present paste composition may have a melting point of at most 750, 800, or 850° C., as determined by a DTA scan.

Although oxygen is typically the predominant anion in the oxide-based component of the present paste composition, some portion of the oxygen may be replaced chemically by fluorine or other halide anions to alter certain properties, such as chemical, thermal, or rheological properties, of the oxide component that affect firing. In an embodiment, up to 10% of the oxygen anions of the oxide composition in any of the formulations of the present paste composition are replaced by one or more halogen anions, including fluorine. For example, up to 10% of the oxygen anions may be replaced by fluorine. Halide anions may be supplied from halides of any of the composition's cations.

One of ordinary skill in the art of glass chemistry would recognize that various components of the present paste composition are described herein as including percentages of certain components. Specifically, the composition of these substances are specified by denominating individual components that may be combined in the specified percentages to form a starting material that subsequently is processed, e.g., as described herein, to form a glass or other fusible material. Such nomenclature is conventional to one of skill in the art. In other words, the oxide-based component contains certain components, and the percentages of those components may be expressed as weight percentages of the corresponding oxide or other forms.

Alternatively, some of the compositions herein are set forth by cation percentages, which are based on the total cations contained in the particular material. Of course, compositions thus specified include the oxygen or other anions associated with the various cations. A skilled person would recognize that compositions could equivalently be specified by weight percentages of the constituents, and would be able to perform the required numerical conversions.

A skilled person would further recognize that the oxide compositions herein, whether specified by weight percentages or cation or molar percentages of the constituent oxides, may alternatively be prepared by supplying the required anions and cations in requisite amounts from different components that, when mixed and fired, yield the same overall composition. For example, in various embodiments, alkali metal cations could be supplied either from the oxide itself or alternatively from any suitable organic or inorganic compound containing the desired cation, such as a carbonate, that decomposes on heating to yield the oxide. The skilled person would also recognize that a certain portion of volatile species, e.g., carbon dioxide, may be released during the process of making a fusible material.

It is known to those skilled in the art that an oxide composition such as one prepared by a melting technique as described herein may be characterized by known analytical methods that include, but are not limited to: Inductively Coupled Plasma-Emission Spectroscopy (ICP-ES), Inductively Coupled Plasma-Atomic Emission Spectroscopy (ICP-AES), and the like. In addition, the following exemplary techniques may be used: X-Ray Fluorescence spectroscopy (XRF), Nuclear Magnetic Resonance spectroscopy (NMR), Electron Paramagnetic Resonance spectroscopy (EPR), Mössbauer spectroscopy, electron microprobe Energy Dispersive Spectroscopy (EDS), electron microprobe Wavelength Dispersive Spectroscopy (WDS), and Cathodoluminescence (CL). A skilled person could calculate percentages of starting components that could be processed to yield a particular fusible material, based on results obtained with such analytical methods.

The embodiments of the various oxide compositions described in the present specification, including the examples below, are not limiting; it is contemplated that one of ordinary skill in the art of glass chemistry could make minor substitutions of additional ingredients and not substantially change the desired properties of the oxide composition, including its interaction with a substrate and any insulating layer thereon.

In an embodiment, the oxide composition may be produced by conventional glass-making techniques and equipment. For example, the ingredients may be weighed and mixed in the requisite proportions and then heated in a platinum alloy crucible in a furnace. The ingredients may be heated to a peak temperature (e.g., 800° C. to 1400° C., or 1000° C. to 1200° C., or 900° C. to 1050° C.) and held for a time such that the material forms a melt that is substantially liquid and homogeneous (e.g., 20 minutes to 2 hours). The melt optionally is stirred, either intermittently or continuously. In an embodiment, the melting process results in a material wherein the constituent chemical elements are homogeneously and intimately mixed at an atomic level. The molten material is then typically quenched in any suitable way including, without limitation, passing it between counter-rotating stainless steel rollers to form 0.25 to 0.50 mm thick platelets, by pouring it onto a thick stainless steel plate, or by pouring it into water or other quench fluid. The resulting particles are then milled to form a powder or frit, which typically may have a d₅₀ of 0.2 to 3.0 μm.

US Patent Application Numbers US 2006/231803 and US 2006/231800, which disclose a method of manufacturing a glass useful in the manufacture of the glass frits described herein, are hereby incorporated by reference herein in their entireties.

Other production techniques may also be used for the present oxide composition and other oxide-based materials. One skilled in the art of producing such materials might therefore employ alternative synthesis techniques including, but not limited to, melting in non-precious metal crucibles, melting in ceramic crucibles, sol-gel, spray pyrolysis, or others appropriate for making powder forms of glass.

In various embodiments, the oxide composition useful in the present paste composition comprises a lead borate comprising two or more intimately mixed oxides selected from a group consisting of lead oxide (PbO), silicon oxide (SiO₂), boron oxide (B₂O₃), and aluminum oxide (Al₂O₃). In such embodiments:

PbO can be any of 40 to 80 mol %, 42 to 73 mol %, or 45 to 68 mol %;

B₂O₃ can be any of 15 to 48 mol %, 20 to 43 mol %, or 22 to 40 mol %;

SiO₂ can be any of 0 to 40 mol %, 0.5 to 36 mol %, 1 to 33 mol %, or 1.3 to 28 mol %; and

Al₂O₃ can be any of 0 to 6 mol %, 0.01 to 5.5 mol %, 0.09 to 4.8 mol %, or 0.5 to 3 mol %,

wherein the foregoing percentages are based on the total molar fraction of each component in the lead borate. Typically the lead borate is partially or fully glassy.

Some embodiments of the present disclosure feature a composition that is lead-free and/or cadmium-free. As used herein, the term “lead-free paste composition” refers to a paste composition to which no lead has been specifically added (either as elemental lead or as a lead-containing alloy, compound, or other like substance), and in which the amount of lead present as a trace component or impurity is 1000 parts per million (ppm) or less by weight. In some embodiments, the amount of lead present as a trace component or impurity is less than 500 ppm, or less than 300 ppm, or less than 100 ppm. Similarly, some embodiments of the present paste composition may comprise cadmium, e.g., in the alkali metal vanadium oxide composition, while others are cadmium-free, again meaning that no Cd metal or compound is specifically added and that the amount present as a trace impurity is less than 1000 ppm, 500 ppm, 300 ppm, or 100 ppm by weight.

For example, the oxide composition may comprise a lead-free composition containing two or more oxides selected from a group consisting of boron oxide (B₂O₃), zinc oxide (ZnO), bismuth oxide (Bi₂O₃), silicon oxide (SiO₂), aluminum oxide (Al₂O₃), and barium oxide (BaO). In such embodiments:

B₂O₃ can be 20 to 48 mol %, 25 to 42 mol %, or 28 to 39 mol %;

ZnO can be 20 to 40 mol %, 25 to 38 mol %, 28 to 36 mol %;

Bi₂O₃ can be 15 to 40 mol %, 18 to 35 mol %, 19 to 30 mol %;

SiO₂ can be 0.5 to 20 mol %, 0.9 to 6 mol %, or 1 to 3 mol %;

Al₂O₃ can be 0.1 to 7 mol %, 0.5 to 5 mol %, or 0.9 to 2 mol %; and

BaO can be 0.5 to 8 mol %, 0.9 to 6 mol %, or 2.5 to 5 mol %,

wherein the foregoing percentages are based on the total molar fraction of each component in the lead-free composition. Typically the lead-free composition is partially or fully glassy.

The oxide compositions described herein, including those described above, are not limited to ones with the exemplified components. It is contemplated that one of ordinary skill in the art of glass chemistry could make minor substitutions of additional ingredients and not substantially change the desired properties of the glass composition. For example, substitutions of glass formers such as P₂O₅ 0-3, GeO₂ 0-3, V₂O₅ 0-3 in mol % can be used either individually or in combination to achieve similar performance for PbO, SiO₂ or B₂O₃. For example, one or more intermediate oxides, such as TiO₂, Ta₂O₅, Nb₂O₅, ZrO₂, CeO₂, and SnO₂ can be added to the glass composition.

In certain embodiments the oxide composition is a glass frit that has a softening point in a range of 250 to 650° C., 300 to 500° C. in another embodiment, 300 to 450° C., or 310 to 400° C. In this specification, “softening point” is determined by differential thermal analysis (DTA). To determine the glass softening point by DTA, sample glass is ground and is introduced with a reference material into a furnace that is heated at a constant rate of 5 to 20° C. per minute. The difference in temperature between the test material and the reference is detected to investigate the evolution and absorption of heat by the test material. In general, the first evolution peak is at the glass transition temperature (Tg), the second evolution peak is at the glass softening point (Ts), and the third evolution peak is at the crystallization point.

The glass frit can be a noncrystalline glass upon firing at 0 to 800° C. in an embodiment. In this specification, “noncrystalline glass” is determined by DTA as described above. The third evolution peak would not appear upon firing at 0 to 800° C. in the DTA of a noncrystalline glass.

In an embodiment, the oxide component comprises any of 0.5% to 5%, 0.5% to 4%, or 1% to 2.5% by weight of the paste composition. Surprisingly and unexpectedly, certain embodiments of the present disclosure permit the fabrication of electrodes contacting p-type emitter regions of n-type base photovoltaic cells using a paste composition with lower amounts of aluminum metal and/or glass frit than previously understood as necessary to achieve satisfactory electrical properties.

### Metal Additive

Certain embodiments of the present paste composition comprise an optional metal additive that can be any one or more of the following: (a) a metal that is one of Pb, Bi, Gd, Ce, Zr, Ti, Mn, Sn, Ru, Fe, Ga, In, TI, Si, or Cr; (b) a metal oxide of one or more of the metals Zn, Pb, Bi, Gd, Ce, Zr, Ti, Mn, Sn, Ru, Co, Fe, Cu, Al, Ga, In, TI, Si, or Cr; (c) any compound that can generate one of the metal oxides of (b) upon firing; or (d) a mixture thereof.

For example, the additive can comprise a Zn-containing additive in an embodiment. The Zn-containing additive can include one or more of the following: (a) Zn, (b) metal oxides of Zn, (c) any compounds that can generate metal oxides of Zn upon firing, or (d) a mixture thereof. The Zn-containing additive may include Zn resinate in another embodiment.

The metal additive in the conductive paste can be present at 2 to 10 parts by weight, based on the weight of the conducting powder.

### Boron Source

In an embodiment, the present paste composition includes a non-oxide boron source, such as elemental boron powder, a non-oxide, boron-containing compound, or a mixture thereof, as part of the inorganic solids.

Exemplary non-oxide, boron-containing compounds useful in the present paste composition include boride compounds of B with Si and Al, such as B₆Si and AlB₂. Other compounds or alloys of B with Si and/or Al may also be used, as well as other non-oxide compounds of B with other metal elements.

The elemental boron or boron-containing compound may comprise 0.1% to 4%, or 0.25% to 3%, or 0.4% to 2.5%, by weight of the paste composition. In another embodiment, the elemental boron or boron-containing compound and any metallic aluminum powder present together comprise 0.5% to 2.5% by weight of the paste composition, of which at most 1% is aluminum in some embodiments.

### Organic Vehicle

The inorganic components of the present composition are typically mixed with an organic vehicle to form a relatively viscous material referred to as a “paste” or an “ink” that has a consistency and rheology that render it suitable for printing processes, including without limitation screen printing. The mixing is typically done with a mechanical system, and the constituents may be combined in any order, as long as they are uniformly dispersed and the final formulation has characteristics such that it can be successfully applied during end use. In an embodiment, the organic medium can be an organic resin or a mixture of an organic resin and an organic solvent.

The proportions of organic vehicle and inorganic components in the present paste composition can vary in accordance with the method of applying the paste and the kind of organic vehicle used. In an embodiment, the present paste composition typically contains its inorganic components in an amount ranging from a lower inorganic limit of any of 50%, 60%, 70%, or 75% to an upper inorganic limit of any of 80%, 85%, 90%, or 95%, by weight of the paste composition. The balance of the paste composition is provided by the organic vehicle.

The organic vehicle typically provides a medium in which the inorganic components are dispersible with a good degree of stability. In particular, the composition preferably has a stability compatible not only with the requisite manufacturing, shipping, and storage, but also with conditions encountered during deposition, e.g., by a screen printing process. Ideally, the rheological properties of the vehicle are such that it lends good application properties to the composition, including stable and uniform dispersion of solids, appropriate viscosity and thixotropy for printing, appropriate wettability of the paste solids and the substrate on which printing will occur, a rapid drying rate after deposition, and stable firing properties.

Substances useful in the formulation of the organic vehicle of the present paste composition include, without limitation, any one or more of the substances disclosed in U.S. Pat. No. 7,494,607 and International Patent Application Publication No. WO 2010/123967 A2, both of which are incorporated herein in their entirety for all purposes, by reference thereto. The disclosed substances include ethyl cellulose, ethylhydroxyethyl cellulose, wood rosin and derivatives thereof, mixtures of ethyl cellulose and phenolic resins, cellulose acetate, cellulose acetate butyrate, polymethacrylates of lower alcohols, monoalkyl ethers of ethylene glycol, monoacetate ester alcohols, and terpenes such as alpha- or beta-terpineol or mixtures thereof with other solvents such as kerosene, dibutylphthalate, butyl carbitol, butyl carbitol acetate, hexylene glycol, and high-boiling alcohols and alcohol esters. The polymer in the organic vehicle may be present in the range of 0.1 wt. % to 5 wt. % of the total paste composition. The organic vehicle may also include naturally-derived ingredients such as various plant-derived oils, saps, resins, or gums.

Solvents useful in the organic vehicle include, without limitation, ester alcohols and terpenes such as alpha- or beta-terpineol or mixtures thereof with other solvents such as kerosene, dibutylphthalate, butyl carbitol, butyl carbitol acetate, hexylene glycol, aromatic solvents, and high-boiling alcohols and alcohol esters. A preferred ester alcohol is the monoisobutyrate of 2,2,4-trimethyl-1,3-pentanediol, which is available commercially from Eastman Chemical (Kingsport, Tenn.) as TEXANOL™. Some embodiments may also incorporate volatile liquids in the organic vehicle to promote rapid hardening after application on the substrate. Various combinations of these and other solvents are formulated to provide the desired viscosity and volatility. The present paste composition may be adjusted as needed to a predetermined, screen-printable viscosity, e.g., by adding additional solvent(s).

In an embodiment, the organic vehicle may include one or more components selected from the group consisting of: bis(2-(2butoxyethoxy)ethyl)adipate, dibasic esters, octyl epoxy tallate, isotetradecanol, and a pentaerythritol ester of hydrogenated rosin. The paste compositions may also include additional additives or components.

The dibasic ester useful in the present paste composition may comprise one or more dimethyl esters selected from the group consisting of dimethyl ester of adipic acid, dimethyl ester of glutaric acid, and dimethyl ester of succinic acid. Various forms of such materials containing different proportions of the dimethyl esters are available under the DBE® trade name from Invista (Wilmington, Del.). For the present paste composition, a preferred version is sold as DBE-3 and is said by the manufacturer to contain 85 to 95 weight percent dimethyl adipate, 5 to 15 weight percent dimethyl glutarate, and 0 to 1.0 weight percent dimethyl succinate based on total weight of dibasic ester.

A wide variety of inert materials can optionally be included in the organic medium of the present composition including, without limitation, an inert, non-aqueous liquid that optionally contains thickeners, binders, dispersants, stabilizers and/or other common additives known to those skilled in the art. By “inert” is meant a material that may be removed by a firing operation without leaving any substantial residue and that has no other effects detrimental to the paste or the final conductor line properties. Additionally, effective amounts of additives, such as surfactants or wetting agents, may be a part of the organic vehicle. Such added surfactant may be included in the organic vehicle in addition to any surfactant included as a coating on the conductive metal powder of the paste composition. Suitable wetting agents include phosphate esters and soya lecithin. Both inorganic and organic thixotropes may also be present.

Among the commonly used organic thixotropic agents are hydrogenated castor oil and derivatives thereof, but other suitable agents may be used instead of, or in addition to, these substances. It is, of course, not always necessary to incorporate a thixotropic agent since the solvent and resin properties coupled with the shear thinning inherent in any suspension may alone be suitable in this regard.

One or more solvents are typically used as a viscosity-adjusting agent. Frequently, the paste composition is formulated with a small solvent holdback, so that the final viscosity can be adjusted to a desired value. Typically, a viscosity of about 300 Pa-s is found to yield good screen printing results, but some variation, for example ±50 Pa-s or more, would be acceptable, depending on the precise printing parameters. The viscosity can be measured conveniently using a Brookfield viscometer (Brookfield Inc., Middleboro, Mass.) with a #14 spindle and a #6 cup, with viscosity values taken after 3 minutes at 10 RPM.

Depending on the aggregate amount of the inorganics included, the content of the organic medium can be 5 to 50 wt. % based on the total weight of the conductive paste composition.

### Manufacturing Solar Cell Electrodes

The present paste composition can be applied as a paste onto a preselected portion of a major surface of the substrate in a variety of different configurations or patterns. The preselected portion may comprise any fraction of the total first major surface area, including substantially all of the area. In an embodiment, the paste is applied on a semiconductor substrate, which may be single-crystal, cast mono, multi-crystal, polycrystalline, or ribbon silicon, or any other semiconductor material.

The application can be accomplished by a variety of deposition processes, including printing. Exemplary deposition processes include, without limitation, plating, extrusion or co-extrusion, dispensing from a syringe, and screen, inkjet, shaped, multiple, and ribbon printing. The paste composition ordinarily is applied over any insulating layer present on the first major surface of the substrate.

The conductive composition may be printed in any useful pattern. For example, the electrode pattern used for the front side of a photovoltaic cell commonly includes a plurality of narrow grid lines or fingers connected to one or more bus bars. In an embodiment, the width of the lines of the conductive fingers may be 20 to 200 μm; 25 to 100 μm; or 35 to 75 μm. In an embodiment, the thickness of the lines of the conductive fingers may be 5 to 50 μm; 10 to 35 μm; or 15 to 30 μm. Such a pattern permits the generated current to be extracted without undue resistive loss, while minimizing the area of the front side obscured by the metallization, which reduces the amount of incoming light energy that can be converted to electrical energy. Ideally, the features of the electrode pattern should be well defined, with a preselected thickness and shape, and have high electrical conductivity and low contact resistance with the underlying structure.

Conductors formed by printing and firing a paste such as that provided herein are often denominated as “thick-film” conductors, since they are ordinarily substantially thicker than traces formed by atomistic processes, such as those used in fabricating integrated circuits. For example, thick-film conductors may have a thickness after firing of about 1 to 100 μm. Consequently, paste compositions that in their processed form provide conductivity and are suitably applied using printing processes are often called “thick-film pastes” or “conductive inks.”

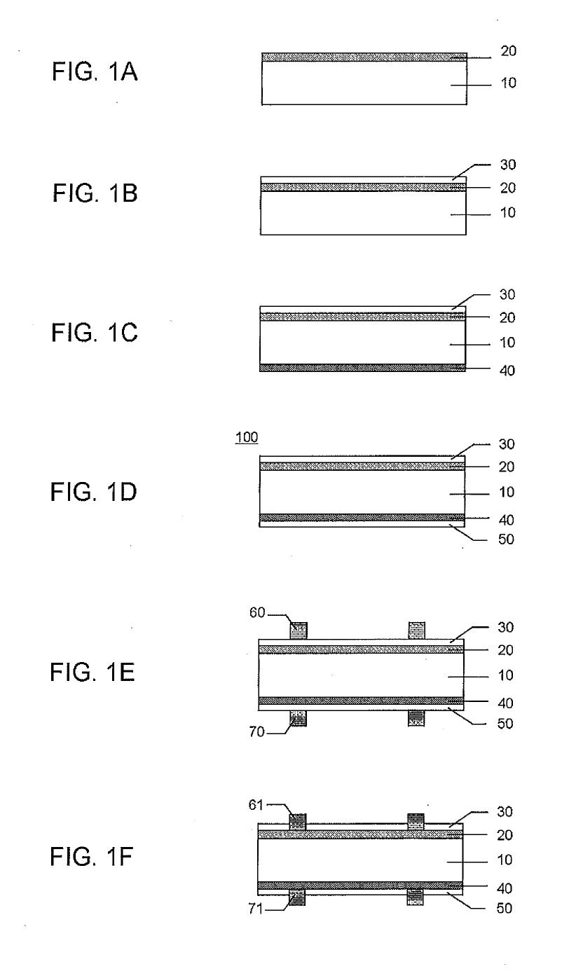

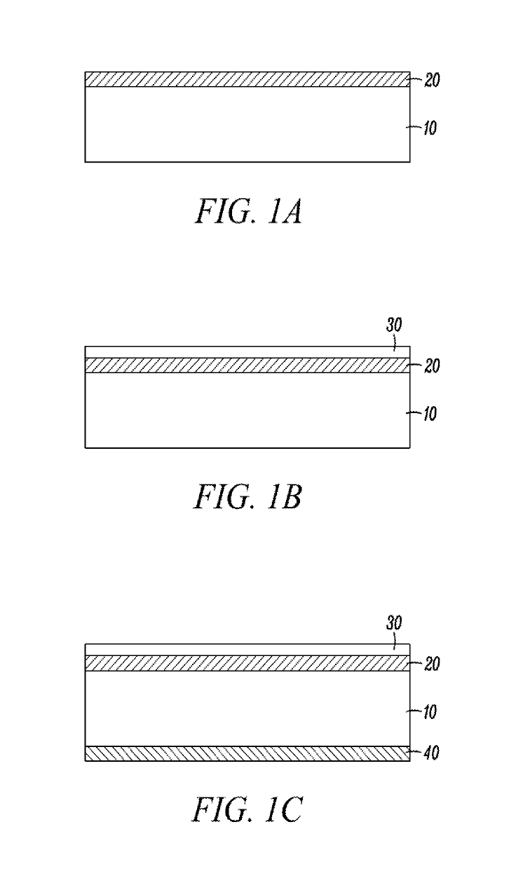

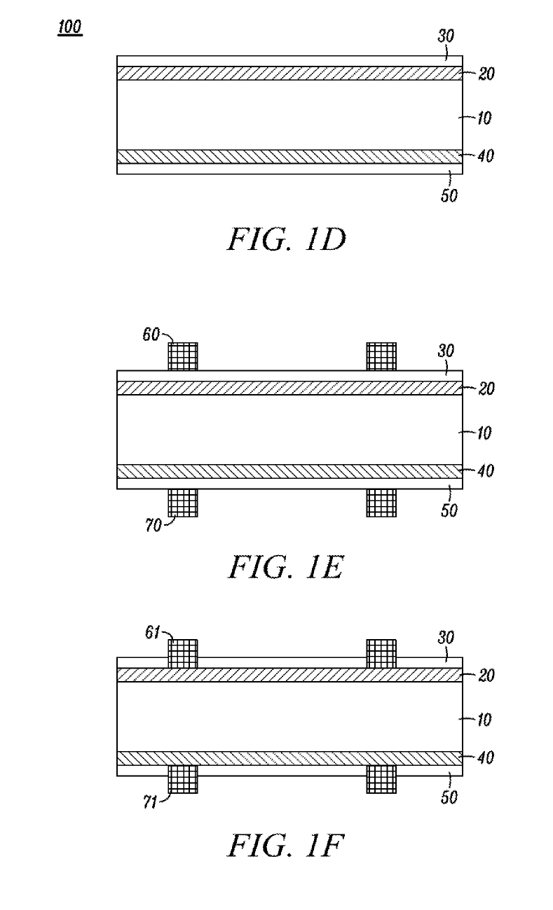

Embodiments of the process provided by the present disclosure are explained below with reference to FIGS. 1A through 1F. The embodiments described below are only examples, and appropriate design changes will be recognized by those skilled in the art.

FIGS. 1A through 1F illustrate steps of a method of manufacturing N-type base solar cells, which employ an N-type base semiconductor substrate comprising a negative layer and a positive layer situated on opposite major surfaces of the substrate. Passivation layers are formed on the negative and positive layers.

In FIG. 1A, a part of an N-type base semiconductor substrate comprising a negative layer 10 and a positive layer 20 is prepared. The positive layer 20 can be formed on one side of the negative layer 10, e.g., by doping with an acceptor impurity, for example by thermal diffusion of boron tribromide (BBr₃) into one side of the negative layer on a first major surface. The N-type base semiconductor substrate can be a silicon substrate. The semiconductor substrate can have a sheet resistance on the order of several tens of ohms per square (Ω/sq).

In FIG. 1B, a passivation layer 30 is formed on the one side of the positive layer 20 on the second major surface. The presence of the passivation layer, especially on the sun-receiving side of the semiconductor substrate, can reduce loss of incident light and/or to reduce loss of charge carriers by recombination of electrons and positive holes at the surface of a substrate. Thus, passivation layer 30 is often termed an anti-reflection coating (ARC) when the passivation layer is configured to reduce loss of incident light. Silicon nitride (SiNₓ), hydrogenated silicon nitride (SiNₓ:H) titanium oxide (TiO₂), aluminum oxide (Al₂O₃), silicon oxide (SiOₓ), tantalum oxide (Ta₂O₅), indium tin oxide (ITO), and silicon carbide (SiCₓ) are exemplary materials for forming a passivation layer. In an embodiment, the passivation layer in the N-type base solar cell is formed from SiO₂, Al₂O₃, SiN, or SiNₓ:H. These materials can be effective for suppressing recombination of electrons and positive holes at the surface of the positive layer. Depending on the particular requirements, passivation layer 30 can have a thickness of 1 to 200 nm.

Al₂O₃ or TiO₂ layers can be formed by an atomic layer deposition (ALD) method. A TiO₂ layer can be formed by a thermal chemical vapor deposition (CVD) method with an organic titanate and water heated at 250° C. to 300° C.

A SiOₓ layer can be formed by a thermal oxidation method, a thermal CVD method, or a plasma-enhanced CVD method. In case of the thermal CVD method, Si₂Cl₄ gas and O₂ gas are heated to a temperature from 700° C. to 900° C. In case of the plasma-enhanced CVD method, SiH₄ gas and O₂ gas, for example, are heated to a temperature from 200° C. to 700° C. A SiOₓ layer can be also formed by a wet oxidation method with nitric acid (HNO₃).

Although not specifically depicted, in some embodiments, the passivation layer comprises multiple sublayers of the same or different materials. For example, the passivation layer 30 can comprise two layers, an Al₂O₃ sublayer formed on the positive layer 20, and a SiNₓ:H sublayer formed atop the Al₂O₃ layer.

As illustrated in FIG. 1C, an n⁺-layer 40 is optionally formed at the other side of the positive layer 20 in the negative layer 10. The n⁺-layer 40 can be omitted. The n⁺-layer 40 contains a donor impurity with higher concentration than that in the negative layer 10. For example, the n⁺-layer 40 can be formed by thermal diffusion of phosphorus into a silicon semiconductor substrate. The presence of an n⁺-layer 40 tends to reduce recombination of electrons and holes at the boundary between negative layer 10 and n⁺-layer 40.

In FIG. 1D, another passivation layer 50 is formed on the n⁺-layer 40. When the n⁺-layer 40 is not included, passivation layer 50 is formed directly formed on the negative layer. The passivation layer 50 can be formed as described above for the passivation layer 30. The passivation layer 50 can be different from the one on the positive layer in terms of its forming material and thickness or forming method. Here, the n-type base semiconductor substrate 100 comprising at least the negative layer 10, the positive layer 20 and the passivation layers thereon is prepared to form a solar cell electrode.

In FIG. 1E, the conductive paste 60 is applied onto the passivation layer 30, which is situated on the positive (p-type material) layer 20, and subsequently dried. The conductive paste 60 can be applied by screen printing. In an embodiment, the pattern of the applied conductive paste 60 is comb-shaped, with plural parallel finger or grid lines that extend generally perpendicularly from a wider bus bar line.

Conductive paste 70 is applied onto the passivation layer 50 on the n⁺-layer 40, e.g., by screen printing. Conductive pastes 60 and 70 can be same or different materials.

In the implementation described here, paste 60 is applied on the positive layer first. However, it will be recognized that paste 70 could also be applied first. Alternatively, both pastes could be applied in a single operation. After pastes 60, 70 are applied, they are optionally dried at a modest temperature to harden the paste composition by removing its most volatile organics, e.g., for 10 seconds to 10 minutes at 150° C. in air.

After printing and drying, the cells are fired to effect a burnout of the organic vehicle from the deposited paste. The firing typically involves volatilization and/or pyrolysis of the organic materials. The firing process is believed to remove the organic vehicle, sinter the conductive metal in the composition, and establish electrical contact between the semiconductor substrate and the fired conductive metal. Firing may be performed in an atmosphere composed of air, nitrogen, an inert gas, or an oxygen-containing mixture such as a mixed gas of oxygen and nitrogen. In an embodiment, the burnout is substantially complete

In one embodiment, the temperature for the firing may be in the range between about 300° C. and about 1000° C., or about 300° C. and about 525° C., or about 300° C. and about 650° C., or about 650° C. and about 1000° C. The firing may be conducted using any suitable heat source. In an embodiment, the firing is accomplished by passing the substrate bearing the printed paste composition pattern through a belt furnace at high transport rates, for example between about 100 and about 500 cm per minute, with resulting hold-up times between about 0.05 and about 5 minutes. Multiple temperature zones may be used to control the desired thermal profile, and the number of zones may vary, for example, between 3 to 11 zones. The temperature of a firing operation conducted using a belt furnace is conventionally specified by the furnace set point in the hottest zone of the furnace, but it is known that the peak temperature attained by the passing substrate in such a process is somewhat lower than the highest set point. Other batch and continuous rapid fire furnace designs known to one of skill in the art are also contemplated.

In an embodiment, firing is carried out in an infrared furnace with a peak set point temperature of from 450° C. to 1000° C., for example. Firing total time can be from 30 seconds to 5 minutes. Firing temperature and time are ordinarily restricted by the need to avoid damaging the semiconductor structure.

As illustrated in FIG. 1F, the conductive pastes 60 and 70 fire through the passivation layers 30 and 50 respectively during the firing so that a p-type solar cell electrode 61 and an n-type solar cell electrode 71 can be formed with a sufficient electrical property.

The solar cell electrode in the present invention can be at least the p-type electrode 61 formed on the positive layer 20 in an embodiment. The solar cell electrode can be both of the p-type electrode 61 and the n-type electrode 71 in another embodiment.

In actual operation, the present N-type solar cell is desirably installed with the positive layer situated on the front (or light receiving) side, and the negative layer located on the opposite back side. The solar cell can be also installed in a reversed configuration.

In another approach, the present paste composition is also usefully employed in processing for manufacture of a back contact type solar cell. The semiconductor substrate of a back contact type solar cell comprises negative and positive layers that are both situated on one side of the semiconductor substrate, with passivation layers formed on both. By locating both electrodes on the side opposite the light-receiving side, the loss of incident light from shading by front side electrodes is eliminated.

One such structure is the so-called “interdigitated back contact” or “IBC” configuration. US2008-0230119, which is incorporated herein in its entirety by reference thereto, discloses one possible form of an IBC configuration that is illustrated by its FIG. 1B. Other configurations of the wafer, including ones in which the p-type and n-type regions are formed by techniques other than grooving, are also contemplated.

### EXAMPLES

The operation and effects of certain embodiments of the present invention may be more fully appreciated from a series of examples (Examples 1-17) described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Examples 1a to 3a

### Paste Preparation

In accordance with the present disclosure, a series of conductive paste compositions are prepared. Each paste composition contains an inorganic solids portion comprising Ag metal powder, a lead borate oxide glass frit, and various amounts of elemental B and/or Al additives that are dispersed in an organic vehicle. The compositions are formulated so they can be screen printed onto silicon wafers and fired to provide a conductive electrode structure.

The organic vehicle is conveniently prepared as a masterbatch using a planetary, centrifugal Thinky® mixer (available from Thinky® USA, Inc., Laguna Hills, Calif.) to mix the ingredients listed in Table I below, with percentages given by weight. TEXANOL™ ester alcohol solvent is available from Eastman Chemical Company, Kingsport, Tenn.

TABLE I
Organic Vehicle Composition

| Ingredient | wt. % |
|---|---|
| 11% ethyl cellulose (50-52% ethoxyl) dissolved | 8.43% |
| in TEXANOL ™ solvent | |
| 8% ethyl cellulose (48-50% ethoxyl) dissolved in | 8.43% |
| TEXANOL ™ solvent | |
| tallowpropylenediaminedioleate | 5.69% |
| pentaerythritol ester of hydrogenated rosin | 29.61% |
| gum damar | 4.27% |
| hydrogenated castor oil derivative | 5.69% |
| dibasic ester | 29.61% |
| aromatic solvent | 1.42% |
| TEXANOL ™ solvent | (balance) |

Lead borate frit suitable for practice of the present invention is manufactured by conventional glass-making techniques, wherein powders of the constituent oxides are combined, melted, quenched, and then pulverized to a desired particle size. Suitable compositions for the lead borate frit include, without limitation, ones disclosed in any of the following patent applications: U.S. application Ser. No. 13/440132, filed Apr. 5, 2012; U.S. application Ser. No. 13/204027, filed Aug. 5, 2011; and U.S. application Ser. No. 14/197334, filed Mar. 5, 2014. Said applications are all included herein in the entirety for all purposes by reference thereto.

The Ag powder used has a predominantly spherical shape and a particle size distribution with a d₅₀ of about 2.3 μm (as measured in an isopropyl alcohol dispersion using a Horiba LA-910 analyzer).

A master paste composition is first prepared by combining the requisite amounts of the Ag powder and the lead borate oxide in a glass jar and tumble-mixing them for about 15 min. This mixture is added by thirds to a jar containing organic vehicle from the aforementioned organic masterbatch and mixed after each addition using the aforementioned Thinky® mixer for 1 minute at 2000 RPM, whereby the ingredients are well dispersed in the organic vehicle. The master paste contains about 90 wt. % Ag powder, about 2 wt. % glass frit, and about 8 wt. % organic vehicle.

After the final addition, the paste is cooled and the viscosity is adjusted to between about 300 and 400 Pa-s by adding solvent and Thinky mixing for 1 minute at 2000 RPM. The paste is then milled on a three-roll mill (Charles Ross and Son, Hauppauge, N.Y.) with a 25 μm gap for 3 passes at zero pressure and 3 passes at 100 psi (689 kPa). Each paste composition is allowed to sit for at least 16 hours after roll milling.

Typical three-roll milling produces pastes sufficiently homogenous to achieve reproducible solar cell performance. A small amount of TEXANOL™ solvent is typically added as needed to adjust the final viscosity to a level permitting the composition to be screen printed onto a substrate. Typically, a viscosity of about 300 Pa-s is found to yield good screen printing results, but some variation, for example ±50 Pa-s or more, would be acceptable, depending on the precise printing parameters. The viscosity can be measured conveniently using a Brookfield viscometer (Brookfield Inc., Middleboro, Mass.) with a #14 spindle and a #6 cup, with viscosity values taken after 3 minutes at 10 RPM.

The pastes of Examples 1a to 3a are prepared by combining the requisite additives with the master paste prepared as described above.

As-received elemental boron (B) powder, which can be obtained from Alfa Aesar®, Ward Hill, Mass., is sieved to −325 mesh before use. The aluminum powder used is approximately spherical, with a d₅₀ of about 3 μm. For convenience, the Al powder is first dispersed in a small amount of organic solvent to form a pre-paste. Providing the Al in this manner makes it easier to introduce and incorporate homogeneously in the final paste compositions herein. However, other techniques may also be used.

The B and/or Al additives are combined with the master paste by another mixing process. The ingredients are placed in a container and mixed in the aforementioned Thinky® mixer for three cycles, each 1-2 min., to fully disperse and mix the ingredients. After each cycle, the batch is cooled to assure effective mixing. The viscosity is again adjusted if needed with additional TEXANOL™ solvent to render it suitable for screen printing fine lines. The amount of additive in each of the paste compositions may be as set forth in Table II.

TABLE II
Paste Compositions with Different Al and B Additive Contents

| Example | wt. % Al additive | wt. % B additive |
|---|---|---|
| 1a | 1.9 | 0 |
| 2a | 0 | 0.4 |
| 3a | 1.9 | 0.4 |

### Examples 1b to 3b

### Fabrication and Testing of Photovoltaic Cells

### Cell Fabrication

Photovoltaic cells are fabricated in accordance with an aspect of the present disclosure using the paste compositions of Examples 1a to 3a to form the front-side electrodes for the cells of Examples 1b to 3b, respectively.

The cells are prepared on planar junction, n-type solar cells with boron-doped emitters and n-type base. In an embodiment, large (˜156 mm×156 mm×˜200 μm thick) monocrystalline wafers, such as those available from International Solar Energy Research Center, Konstanz, Germany, may be used. The textured front surface of these wafers is diffused with boron to create an emitter with sheet resistance of ˜70-75 ohm/sq, while the smoother back surface is doped with phosphorus to create a back surface field. A silicon nitride/silicon oxide anti-reflective coating is present on both surfaces.

For convenience, the experiments are carried out using 28 mm×28 mm “cut down” wafers prepared by dicing the large starting wafers with a diamond blade saw. The paste compositions of Examples 1a to 3a are screen-printed in a comb-like pattern comprising 13 fingers extending perpendicularly from a bus bar on the front surface of these wafers. The deposition is done using a semi-automatic, AMI-Presco (AMI, North Branch, N.J.) MSP-485 screen printer.

A commercial Ag paste composition, SOLAMET® PV17F (available from DuPont Corporation, Wilmington, Del.), is screen printed on the back surface of these wafers using the same press to provide the opposite polarity electrode. The PV17F paste composition is known to permit the creation of electrodes that provide good electrical contact to n-type, phosphorus-doped silicon wafers. A similar comb-like screen with 13 fingers (pitch ˜0.20 cm) is used for the back side printing.

After printing and drying the pastes, the wafers are fired in a BTU rapid thermal processing, multi-zone belt furnace (BTU International, North Billerica, Mass.). At least nine wafers are printed using each paste, so that at least three can be fired at each peak set point temperature of the belt furnace. The temperature set points chosen are between 865 and 915° C. After firing, the median front-side conductor line width is ˜80-100 μm and the mean line height is ˜10-15 μm. The bus bar is 1.25 mm wide. The median line width of the conductive fingers of the back side electrode is ˜200 μm. Performance of “cut-down” 28 mm×28 mm cells is known to be impacted by edge effects which reduce the overall photovoltaic cell efficiency by as much as ˜1-3% from what would be obtained with full-size wafers.

### Electrical Testing

Electrical properties of the photovoltaic cells of Examples 1b to 3b as thus fabricated are measured at 25±1.0° C. using an ST-1000 IV tester (Telecom STV Co., Moscow, Russia). The Xe arc lamp in the IV tester simulates sunlight with a known intensity and irradiates the front surface of the cell. The tester uses a four contact method to measure current (I) and voltage (V) at approximately 400 load resistance settings to determine the cell's I-V curve under an illumination of 1 Sun. Efficiency (Eff), fill factor (FF), and series resistance (Rₐ) are obtained from the I-V curve for each cell. Rₐ is defined in a conventional manner as the negative of the reciprocal of the local slope of the IV curve near the open circuit voltage. As recognized by a person of ordinary skill, Rₐ is conveniently determined and a close approximation for Rₛ, the true series resistance of the cell. For each composition, an optimum firing temperature is identified as the temperature that results in the highest mean or median efficiency, based on 3-cell test groups for each paste composition and temperature. Mean electrical results for the cell groups fired at the respective optimal firing temperature are depicted in Table III below. Of course, this testing protocol is exemplary and other equipment and procedures for testing efficiencies will be recognized by one of ordinary skill in the art.

TABLE III
Electrical Properties of N-Type Monocrystalline Solar Cells

| | Al | B | Eff. | FF | Ra |
|---|---|---|---|---|---|
| Example | (wt. %) | (wt. %) | (%) | (%) | (Ω) |
| 1b | 1.9 | 0 | 2.95 | 30.7 | 3.59 |
| 2b | 0 | 0.4 | 4.39 | 28.3 | 2.93 |
| 3b | 1.9 | 0.4 | 17.46 | 73.3 | 0.185 |

Examples 1b to 3b demonstrate that the inclusion of both elemental B and Al in a paste composition that incorporates a relatively low amount of a lead borate frit is effective in promoting the formation of an electrode that affords a good electrical connection to the B-doped front side emitters of n-type Si solar cells. The cells exhibit better electrical properties, including one or more of higher efficiency, higher fill factor, and lower series resistance, than cells having electrodes made with conventional conductive paste compositions that typically include a higher concentration of the glass frit.

### Examples 4a to 6a

### Paste Preparation

The paste compositions of Examples 4a to 6a are formulated using the same procedures set forth above for Examples 1a to 3a, except that boron is supplied from the boron-containing compound B₆Si, instead of elemental B. As in Examples 1a to 3a, all the constituents except for the additives (Al metal and/or the B₆Si compound) are formulated as a masterbatch, to which the requisite additives are added in a subsequent step using the Thinky® mixer. The amount of additive in each of the paste compositions may be as set forth in Table IV.

TABLE IV
Paste Compositions with Different Al and B₆Si Additive Contents

| Example | wt. % Al additive | wt. % B₆Si additive |
|---|---|---|
| 4a | 0.95 | 0 |
| 5a | 0 | 0.8 |
| 6a | 0.95 | 0.8 |

### Examples 4b to 6b

### Fabrication and Testing of Photovoltaic Cells

### Cell Fabrication

Photovoltaic cells are fabricated in accordance with an aspect of the present disclosure using the paste compositions of Examples 4a to 6a to form front-side electrodes for the cells of Examples 4b to 6b, respectively. The same fabrication and testing procedures used for Examples 1b to 3b are also used for the cells of Examples 4b to 6b, and yield the electrical testing results provided in Table V.

TABLE V
Electrical Properties ofN-Type Monocrystalline Solar Cells

| | Al | B₆Si | Eff. | FF | Ra |
|---|---|---|---|---|---|
| Example | (wt. %) | (wt. %) | (%) | (%) | (Ω) |
| 4b | 0.95 | 0 | 11.08 | 49.13 | 0.519 |
| 5b | 0 | 0.8 | 3.58 | 28.1 | 3.358 |
| 6b | 0.95 | 0.8 | 17.27 | 73.6 | 0.167 |

Examples 4b to 6b demonstrate that the inclusion of both elemental Al and a B₆Si additive in a paste composition that includes a relatively low amount of lead borate frit is effective in promoting the formation of an electrode that affords a good electrical connection to the B-doped front side emitters of n-type Si solar cells. The cells exhibit better electrical properties, including one or more of higher efficiency, higher fill factor, and lower series resistance, than cells having electrodes made with conventional conductive paste compositions that typically include a higher concentration of the glass frit.

### Examples 7a to 10a

### Paste Preparation

Examples 4 to 6 are extended by formulating the paste compositions of Examples 7a to 10a. The paste compositions are all prepared using the same processes described above for Examples 1a to 6a. The Example 7a paste composition is prepared with 1.9 wt. % Al supplied from the aforementioned Al pre-paste, but without any other added boron-containing compound. Examples 8a to 10a also include 1.9 wt. % Al from the pre-paste, along with 0.6 wt. % of various alternative B-containing compounds as additives, as set forth in Table VI. The various additive powders are sieved through a 325 mesh screen prior to being incorporated in the same master paste composition used for Examples 1a to 6a.

TABLE VI
Paste Compositions with Different Boron Sources

| | boron-containing |
|---|---|
| Example | compound |
| 7a | none |
| 8a | B₆Si |
| 9a | AlB2 |
| 10a | BN |

### Examples 7b to 10b

### Fabrication and Testing of Photovoltaic Cells

The paste compositions of Examples 7a to 10a are used to prepare front-side electrodes for the photovoltaic cells of Examples 7b to 10b, respectively. The procedures used to fabricate and test cells in Examples 1b to 6b, including use of SOLAMET® PV17F for the back side electrodes, are again used for Examples 7b to 10b. Results of the electrical testing are shown in Table VII.

TABLE VII
Electrical Properties of N-Type Photovoltaic Cells

| | | Eff. | FF | Ra |
|---|---|---|---|---|
| Example | boron source | (%) | (%) | (Ω) |
| 7b | (none) | 4.48 | 32.72 | 2.16 |
| 8b | B₆Si | 16.9 | 73.35 | 0.175 |
| 9b | AlB₂ | 16.7 | 73.12 | 0.195 |
| 10b | BN | 4.63 | 31.57 | 2.27 |

These examples demonstrate that B sourced from different B-containing compounds may have different efficacy in promoting formation of high quality conductive structures in contact with the p-doped emitter regions of n-type photovoltaic cells. Inclusion of B₆Si and AlB₂ additives (Examples 8b and 9b) significantly improves the electrical properties over those afforded without B addition (Example 7b). Inclusion of BN, another B source, at the same level, (Examples 10b), results in improved properties, albeit to a lesser extent.

### Examples 11a to 12a

Examples 6 and 8 above are extended to paste compositions with different amounts of lead borate frit, Al, and B₆Si. The paste compositions of Examples 11a and 12a shown in Table VIII are again prepared by formulating a master paste composition, then incorporating the desired amounts of Al and B₆Si as described above.

TABLE VIII
Paste Compositions with Different Additive Amounts

| | | glass frit | B₆Si | Al |
|---|---|---|---|---|
| Example | Paste | (wt. %) | (wt. %) | (wt. %) |
| 11a | B₆Si-1 | 2.5% | 0.8% | 1.2% |
| 12a | B₆Si-2 | 2.5% | 0.4% | 0.4% |

### Examples 11b to 12b

### Fabrication and Testing of Photovoltaic Cells

Using the same techniques employed for Examples 1b to 10b, the paste compositions of Examples 11a and 12a are used to prepare front-side electrodes for the photovoltaic cells of Examples 11b and 12b, respectively. SOLAMET® PV17F paste composition is used for back side electrodes.

The electrical properties of the cells of Examples 11b and 12b are tested as before, yielding the results set forth in Table IX. Open circuit voltage V_{oc} and short-circuit current I_{sc} are determined using the ST-1000 IV tester.

In addition, the contact resistance (R_{c}) between the electrodes and the n-type silicon layer are measured for these cells. For example, the measurement can be carried out using a 4-point method employing a source meter (Gamry Reference 600 Potentiostat/Galvanostat/ZRA, available from Gamry Instruments, Warminster, Pa.) and an appropriate set of current and voltage probes. Samples suitable for this measurement are prepared by first cutting off the bus bar of a solar cell with a dicing saw, and then cutting perpendicular to the fingers, the remaining contact grid into two stripes of 1 cm width. The electrical measurement is then carried out using the following two steps: (1) the voltage between the inner two lines is measured while a direct current flows through them, to yield (via Ohm's law) a sum (2×R_{c}+Rₛₕₑₑₜ), where R_{c} is the average contact resistance of the inner two contacts and Rₛₕₑₑₜ is the sheet resistance of the substrate between the inner two contacts; (2) the voltage between the inner two lines is measured while a direct current flows between the outer two contacts, to yield Rₛₕₑₑₜ between the inner two contacts. The difference between the two measured values divided by two closely approximates the average R_{c} of the inner two contacts. The direct current used for these measurements is typically about 10 mA.

The contact resistivity (π_{c}) is calculated by multiplying the value of R_{c} thus measured by the measured contact area, π_{c}=R_{c}×d×W, wherein d represents line width and W represents line length. Other similar measurement techniques can also be used to obtain these results. For example, a transfer length method (TLM) can be used to obtain an R_{c} value from four neighboring lines. One such method is described in “Semiconductor Material and Device Characterization” 3rd Ed., D. K. Schroder, Wiley-Interscience, New Jersey, 2006, page 147. The line resistivity is determined conventionally by measuring the resistance of a finger line using a four-terminal technique, then calculating the resistivity from measured dimensions of the line.

TABLE IX
Electrical Properties of N-Type Photovoltaic Cells

| | | | | | | Line | |
|---|---|---|---|---|---|---|---|
| | Eff. | Voc | Isc | FF | Rₐ | resistivity | ρ_{c} |
| Example | (%) | (V) | (A) | (%) | (Ω) | (μΩ · cm) | (mΩ · cm²) |
| 11b | 17.54 | 0.624 | 0.299 | 73.23 | 0.164 | 3.43 | 0.94 |
| 12b | 17.47 | 0.628 | 0.299 | 72.33 | 0.172 | 2.30 | 2.03 |

As shown here, electrodes formed with the Example 11a paste composition achieve lower contact resistivity π_{c} than obtained with conventional commercial pastes appointed for fabricating electrodes contacting the p-type emitters of n-base photovoltaic cells. A reduced π_{c} typically helps to reduce series resistance Rₐ and improve fill factor FF, so as to achieve better cell efficiency. Although the electrodes of the Example 12b cells (made with the Example 12a paste composition) show a lesser reduction of π_{c}, they show a greater reduction in line resistivity and higher V_{oc} and fill factor, so that overall cell efficiency is still improved over that of cells made with a typical commercial paste composition.

### Examples 13a to 17a

### Paste Preparation

Paste compositions containing various combinations of Al metal, B₆Si, and AlB₂ are formulated as Examples 13a to 17a listed in Table X. The pastes are prepared in the manner described above for Examples 8a and 9a, wherein a master paste containing 2 wt. % lead borate glass is prepared first as Example 13a. The remaining Examples 14a to 17a are made by adding the requisite additives and then mixing the combined material as before.

TABLE X
Paste Compositions with Different AlB₂/B₆Si/Al Contents

| | | AlB₂ | B₆Si | Al |
|---|---|---|---|---|
| Example | Paste | (wt. %) | (wt. %) | (wt. %) |
| 13a | No additive | 0% | 0% | 0% |
| 14a | AlB2-1 | 1.0% | 0% | 0.5% |
| 15a | AlB2-2 | 0.5% | 0.2% | 0.3% |
| 16a | AlB2-3 | 1.5% | 0% | 0% |
| 17a | AlB2-4 | 1.0% | 0.5% | 0% |

### Examples 13b to 17b

### Fabrication and Testing of Photovoltaic Cells

The paste compositions of Examples 13a to 17a are used to prepare front-side electrodes for the photovoltaic cells of Examples 13b to 17b, respectively, using the same protocols employed for Examples 1b to 3b. Back side electrodes are prepared with SOLAMET® PV17F paste.

All the cells are electrically tested as before, yielding the results shown in Table XI.

TABLE XI
Electrical Properties of N-Type Photovoltaic Cells

| | | AlB₂ | B₆Si | Al | Eff | V_{oc} | I_{sc} | FF | Rₐ |
|---|---|---|---|---|---|---|---|---|---|
| Example | Paste | (wt. %) | (wt. %) | (wt. %) | (%) | (V) | (A) | (%) | (Ω) |
| 13b | No additive | 0% | 0% | 0% | 5.77 | 0.634 | 0.243 | 29.2 | 2.15 |
| 14b | AlB2-1 | 1.0% | 0% | 0.5% | 17.84 | 0.629 | 0.304 | 72.95 | 0.162 |
| 15b | AlB2-2 | 0.5% | 0.2% | 0.3% | 17.76 | 0.63 | 0.303 | 72.22 | 0.169 |
| 16b | AlB2-3 | 1.5% | 0% | 0% | 15.47 | 0.625 | 0.301 | 64.25 | 0.301 |
| 17b | AlB2-4 | 1.0% | 0.5% | 0% | 14.95 | 0.624 | 0.302 | 61.6 | 0.343 |

These results set forth in Table XI demonstrate that certain paste formulations that include AlB₂ and/or B₆Si can be used to form electrodes contacting p-type emitters of n-type base photovoltaic cells that exhibit electrical properties superior to those with electrodes formed with conventional paste compositions.

It is further surprising and unexpected that certain formulations (e.g. Examples 16 and 17) produce operable photovoltaic cells without the inclusion of Al metal powder. It has generally been regarded in the art that the presence of Al is required to form an electrode that made a satisfactory connection to a boron-doped emitter.

Having thus described the invention in rather full detail, it will be understood that this detail need not be strictly adhered to but that further changes and modifications may suggest themselves to one skilled in the art, all falling within the scope of the invention as defined by the subjoined claims.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. For example, the present paste composition, or a constituent thereof, may be recited as “consisting essentially of” certain substances. The presence of a small amount of an additional substance in the paste composition or its constituent would not substantially alter the functional properties of the paste compositions or a fired device manufactured using the paste composition.

The skilled person will also recognize that raw materials used in the present formulation often unintentionally include impurities that may be incorporated into the oxide composition or other paste constituents during processing. These incidental impurities may be present in the range of hundreds to thousands of parts per million. Impurities commonly occurring in industrial materials used herein are known to one of ordinary skill. The presence of such impurities would not substantially alter the properties of the present oxide component, paste compositions made with the oxide component, or a fired device manufactured using the paste composition. Thus, and without limitation, a solar cell employing a conductive structure made using the present paste composition may have the efficiency and other electrical properties described herein, even if the composition includes a small amount of impurities. Likewise, a small residue from incomplete removal of the organic medium of the paste composition during firing may also be acceptable if no appreciable degradation of the mechanical or electronic properties of the solar cell results.

Further embodiments of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

For the sake of convenience and definiteness, specific test procedures are identified herein for determining certain electrical and other properties of the present paste composition and devices made therewith. However, a person of ordinary skill will understand that there may be other published or recognized methods or test procedures that could be used to determine such properties, and that the different procedures can, in some instances, yield different results for the same property. A skilled person would further expect some variation in experimental measurement of properties. All numerical values set forth herein should thus be considered to be “about” or “approximately” the stated value, in view of the nature of testing in general.

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage,

(a) amounts, sizes, ranges, formulations, parameters, and other quantities and characteristics recited herein, particularly when modified by the term “about”, may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value; and

(b) all numerical quantities of parts, percentage, or ratio are given as parts, percentage, or ratio by weight; the stated parts, percentage, or ratio by weight may or may not add up to 100.

What is claimed is:

1. A paste composition comprising:
(a) a source of silver metal;
(b) 0.5% to 5% of a fusible material comprising two or more intimately mixed oxides selected from the group consisting of lead oxide (PbO), boron oxide (B₂O₃), zinc oxide (ZnO), bismuth oxide (Bi₂O₃), silicon oxide (SiO₂), aluminum oxide (Al₂O₃), and barium oxide (BaO);
(c) 0.1% to 4% of a boron source comprising at least one of elemental boron, a non-oxide, boron-containing compound, or a combination thereof; and
(d) an organic vehicle in which components (a) to (c) are dispersed,
wherein the percentages are based on weight of the paste composition.

2. The paste composition of claim 1, further comprising 0.1% to 4% of aluminum metal powder dispersed in the organic vehicle, based on weight of the paste composition.

3. The paste composition of claim 1, wherein the fusible material is a lead borate.

4. The paste composition of claim 3, wherein the fusible material comprises:
(a) 40 to 80 mole % of PbO;
(b) 0.5 to 40 mole % of SiO₂;
(c) 15 to 48 mole % of B₂O₃; and
(d) 0.01 to 6 mole % of Al₂O₃, based on the total lead borate fusible material.

5. The paste composition of claim 1, wherein the boron source comprises 0.25% to 3% elemental boron by weight of the paste composition.

6. The paste composition of claim 1, wherein the boron source consists essentially of elemental boron.

7. The paste composition of claim 1, wherein the boron source comprises one or more non-oxide, boron-containing compounds.

8. The paste composition of claim 7, wherein the boron source comprises a non-oxide, boron-containing compound that comprises aluminum or silicon.

9. The paste composition of claim 8, wherein the boron source comprises SiB₆.

10. The paste composition of claim 8, wherein the boron source comprises AlB₂.

11. The paste composition of claim 2, wherein the boron source and the aluminum powder together comprise 0.5% to 2.5% by weight of the paste composition.

12. The paste composition of claim 2, wherein the aluminum powder comprises at most 1% by weight of the paste composition.

13. The paste composition of claim 1, which is substantially free of aluminum metal.

14. The paste composition of claim 1, wherein the source of silver metal is a silver metal powder.

15. A process for forming an electrically conductive structure on a substrate, the process comprising:
(a) providing a substrate having a first major surface and a first passivation layer on at least a portion of the first major surface;
(b) applying a paste composition onto a preselected portion of the first passivation layer on the first major surface, wherein the paste composition comprises:
(i) a source of silver metal,
(ii) 0.5% to 5% of a fusible material comprising two or more intimately mixed oxides selected from the group consisting of lead oxide (PbO), boron oxide (B₂O₃), zinc oxide (ZnO), bismuth oxide (Bi₂O₃), silicon oxide (SiO₂), aluminum oxide (Al₂O₃), and barium oxide (BaO),
(iii) 0.1% to 4% of a boron source comprising at least one of elemental boron, a non-oxide, boron-containing compound, or a combination thereof, and
(iv) an organic vehicle in which components (i) to (iii) are dispersed,
wherein the percentages are based on weight of the paste composition;
(c) firing the substrate and paste composition thereon, wherein the first passivation layer is penetrated and the silver metal is sintered during the firing to form the electrically conductive structure and provide electrical contact between the electrically conductive structure and the substrate.

16. The process of claim 15, wherein the substrate is a semiconductor and the preselected portion of the first passivation layer is situated on p-type material.

17. The process of claim 15, wherein the first passivation layer comprises aluminum oxide, titanium oxide, silicon nitride, SiNₓ:H, silicon oxide, or silicon oxide/titanium oxide.

18. An electrically conductive structure formed by the process of claim 15.

19. An article comprising a substrate and an electrically conductive structure thereon, the article having been formed by the process of claim 15.

20. The article of claim 19, wherein the article comprises a semiconductor device.

21. The article of claim 20, wherein the article comprises a photovoltaic cell.
